(19) United States
(12) Patent Application Publication
(10) Pub. No.: US 2002/0098442 A1
(43) Pub. Date: Jul. 25, 2002

(54) Resist resins, chemically amplified resist composition, and process for the formation of a pattern

(75) Inventor: Mitsuharu Yamana, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/991,691

(22) Filed: Nov. 26, 2001

(30) Foreign Application Priority Data
Nov. 24, 2000 (JP) 2000-357781

(51) Int. Cl. G03F 7/004

(52) U.S. Cl. 430/270.1; 526/319; 430/326

(57) ABSTRACT

A resist resin has a molecular structure in which protecting groups bond to a base resin such that elimination of the protecting groups from the resist resin increases its alkali-solubility. The protecting groups are residual groups represented by the following formula (I):

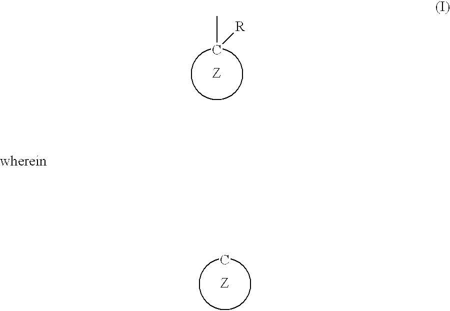

represents a substituted or unsubstituted, fused ring having 12 to 25 carbon atoms, and R represents an alkyl group having 1 to 4 carbon atoms. The resist resin is excellent in etch resistance, resist resolution and substrate adhesion and also in various other properties required for resist resins.

### TECHNICAL FIELD

This invention relates to chemically amplified resist resins which are suitable for use in microfabrication technology relying upon shortwave lasers.

### BACKGROUND OF THE INVENTION

Intensive technological developments are currently under way on ArF lithography as next-generation exposure technology beyond 0.13 μm. The ArF excimer laser has a wavelength of 193 nm, and is expected to achieve a still higher resolution than the KrF excimer laser which has been used conventionally.

Use of such a shortwave laser, however, precludes employing aromatic-ring-containing resist resins which have been used to date, because marked absorption of laser beams takes place.

Applications of alicyclic-group-containing resin materials as resist resins are hence under study. Those employed as resist resins for the ArF excimer laser include the following resins:

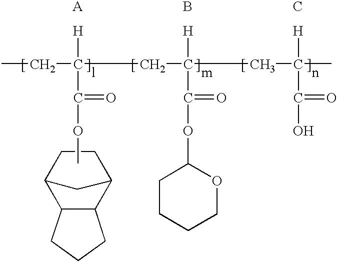

In the above-described resist resins, the structural unit A has a function to impart etch resistance. The structural unit B is a segment in which a protecting group is bonded to a base resin, and plays a role to have resist resolution exhibited. On the other hand, the structural unit C is a segment which imparts substrate adhesion. As these structural units are designed to impart etch resistance, resist resolution and substrate adhesion, respectively, an attempt to improve one of these properties unavoidably leads to reductions in the remaining properties. It has, therefore, been difficult to sufficiently improve all of these properties in the conventional art.

As the structures of protecting groups in conventional resist resins, the following structures are known as disclosed, for example, in JP-A 11-352694.

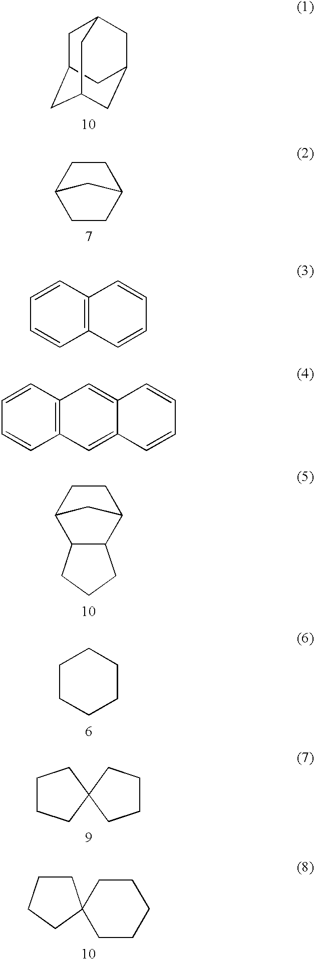

wherein the numbers affixed to some of the formulas indicate the numbers of carbon atoms making up the respective rings.

Of the above-described protecting groups, the protecting groups (3) and (4) are hardly applicable to lithography making use of an exposure radiation source of 200 nm or shorter in wavelength, because they contain a π electron conjugated system and have an absorption band in the ultraviolet range. All the remaining protecting groups have a carbon number of 10 or less and do not have sufficient etch resistance.

### SUMMARY OF THE INVENTION

The present invention has as an object thereof the provision of a resist resin excellent in etch resistance, resist resolution and substrate adhesion and also superb in various other properties required for resist resins, a chemically amplified resist composition making use of the resist resin and a pattern forming process.

A resist resin according to the present invention has a molecular structure in which protecting groups bond to a base resin such that elimination of said protecting groups from said resist resin increases its alkali-solubility, and is characterized in that the protecting groups are residual groups represented by the following formula (I):

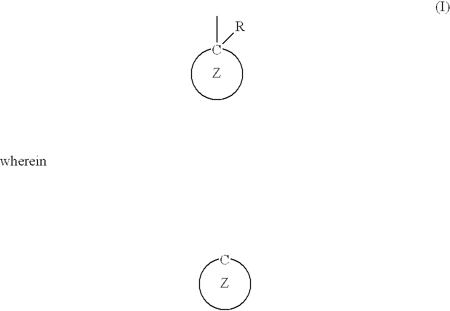

represents a substituted or unsubstituted, fused ring having 12 to 25 carbon atoms, and R represents an alkyl group having 1 to 4 carbon atoms.

Further, another resist resin according to the present invention is characterized by comprising units represented by the following formula (A):

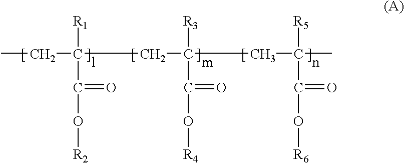

wherein R₁, R₃ and R₅ each independently represent a hydrogen atom or a methyl group, R₂ represents an alicyclic hydrocarbon group having 7 to 25 carbon atoms, a protecting group R₄ is a residual group represented by the following formula (I):

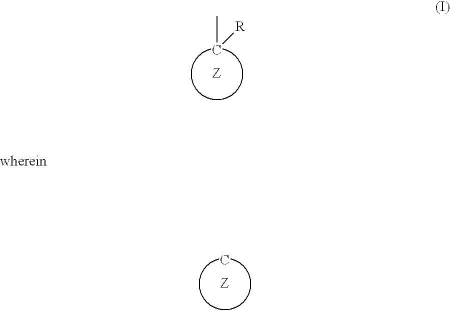

represents a substituted or unsubstituted, fused ring having 12 to 25 carbon atoms, R represents an alkyl group having 1 to 4 carbon atoms, R₆ represents a hydrogen atom or a γ-butyrolactonyl group, l, m and n each represent the content by percentage of the units, l+m+n=100, 0<l<100, 0<m<100, and 0<n<100.

Furthermore, a chemically amplified resist composition according to the present invention is characterized by comprising 75 to 99.8 wt. % of one of the above-described resist resins and 0.2 to 25 wt. % of a photoacid generator.

Still furthermore, a pattern forming process according to the present invention is characterized by comprising the steps of:

coating the above-described chemically amplified resist composition onto a substrate;

heating a resulting coating film;

exposing said heated coating film to high-energy radiation;

subjecting said exposed coating film to heat treatment; and

developing said heat-treated coating film to form a pattern.

The present invention has structurally specified protecting groups of a resist resin and therefore, the resist resin is excellent in etch resistance, resist resolution and substrate adhesion and also in various other properties required for resist resins. Relying upon a chemically amplified resist composition and a pattern forming process both of which make-use of this resist resin, microfabrication of such a high level as not available to date can be achieved.

### DETAILED DESCRIPTION OF THE EMBODIMENTS

Each resist resin in the present invention has a molecular structure in which protecting groups bond to a base resin and becomes alkali-soluble by elimination of the protecting groups, so that the resist resin has a molecular structure in which alkali-soluble groups are blocked by the protecting groups. Illustrative of the alkali-soluble groups are carboxyl groups. When carboxyl groups are contained as the alkali-soluble groups, the resist resin takes a structure that the protecting groups are bonded to the base resin via ester bonds. By taking such a structure, the protecting groups are readily eliminated so that the resist resin is rendered alkali-soluble. As a result, the resist is provided with good resolution.

The resist resin in the present invention is used preferably in combination with a photoacid generator. In this case, an acid generated from the photoacid generator upon exposure to light eliminates the protecting groups so that the alkali-soluble groups are exposed to render the resist resin alkali-soluble.

As the base resin in the present invention, a variety of resins can be used. Nonetheless, use of a resin of the polycarboxylate ester skeleton is preferred.

It is preferred for the resist resin in the present invention that α, which is defined by the following formula:

α=N/(N_{C}−N_{O})

where

N means a total number of atoms in said resist resin,

N_{C} means a number of carbon atoms in said resist resin and

N_{O} means a number of oxygen atoms in said resist resin, is not greater than 3.1. Setting of a at such a value makes it possible to provide the resist resin with further improved resist durability.

It is not preferred for the resist resin in the present invention to contain aromatic rings, because aromatic rings generally have an absorption band around 200 nm and a resist resin with aromatic rings is hardly usable as a resist for the ArF laser.

Preferred examples of the resist resins according to the present invention include those comprising units represented by the following formula (A):

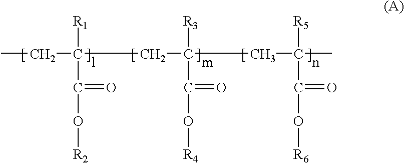

wherein R₁, R₃ and R₅ each independently represent a hydrogen atom or a methyl group, R₂ represents an alicyclic hydrocarbon group having 7 to 25 carbon atoms, a protecting group R₄ is a residual group represented by the following formula (I):

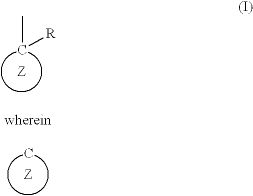

represents a substituted or unsubstituted, fused ring having 12 to 25 carbon atoms, R represents an alkyl group having 1 to 4 carbon atoms, R₆ represents a hydrogen atom or a γ-butyrolactonyl group, l, m and n each represent the content by percentage of the units, l+m+n=100, 0<l<100, 0<m<100, and 0<n<100.

The protecting groups in the present invention (R₄ in the formula(A)) have good etch resistance by themselves. Groups having 10 or fewer carbon atoms, such as a tetrahydropyranyl group or tricyclodecanyl group, have been used in conventional resist resins. Instead of such protecting groups, groups having 12 to 25 carbon atoms are chosen as protecting groups, and more preferably, protecting groups such as those providing the resist resin with an overall carbon density of 3.1 or lower are chosen in the present invention as described above. The resulting resist resin is, therefore, provided with excellent etch resistance.

The protecting groups in the present invention have a structure represented by the following formula (I):

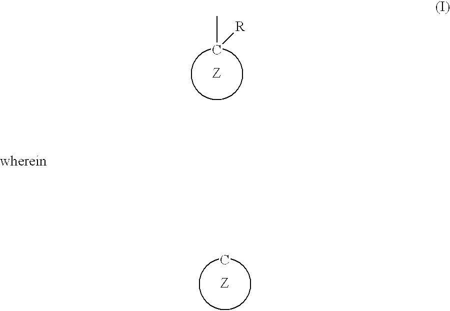

represents a substituted or unsubstituted, fused ring having 12 to 25 carbon atoms, and R represents an alkyl group having 1 to 4 carbon atoms. owing to the inclusion of fused ring having 12 to 25 carbon atoms, the protecting groups themselves have etch resistance, thereby making it possible to enhance etch resistance without impairing substrate adhesion or resolution.

In general, a protecting group with a fused ring having 12 to 25 carbon atoms cannot be readily eliminated with an acid. The present invention, therefore, has adopted the structure that an alkyl group having 1 to 4 carbon atoms is additionally bonded to the site of bonding to the base resin, specifically to the carbon atom via which the protecting group is bonded to the base resin. This alkyl group facilitates elimination of the protecting group with an acid, thereby achieving an improvement in etching resolution. Particularly preferred as this alkyl group is a methyl group or an ethyl group, because the elimination of the protecting group can be facilitated still further.

The fused ring in the present invention is formed of two or more rings fused together, and may desirably be a ring having no π electron conjugated system, with an alicyclic ring being particularly desired. Desirably, the fused ring has a structure that does not contain any hetero atoms such as oxygen, nitrogen or sulfur in the ring. Further, the fused ring desirably does not contain a C═O bond or the like. Such a structure makes it possible to practically avoid absorption of an ultraviolet ray of 200 nm or shorter and hence, to provide a resist resin suitable for use in lithography making use of light of a short wavelength such as the ArF laser.

Specific examples of the fused ring represented by:

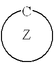

in the above-described protecting group include tricyclo[5.2.1.0^{2.6}]decyl, hexacyclo[6.6.1.1^{3.6}.1^{10.13} .0^{2.7}.0^{9.14}]heptadecyl, octacyclo[8.8.1^{2.9}.1^{4.7}. 1^{11.18}.1^{13.16}.0.0^{3.8}.0^{12.17}]docosyl, cholestanyl, and derivatives thereof. Examples of preferred protecting groups include the following protecting groups:

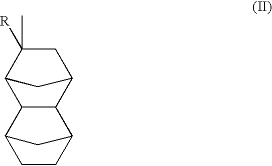

wherein R represents an alkyl group having 1 to 4 carbon atoms.

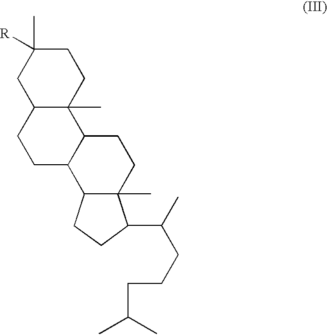

wherein R represents an alkyl group having 1 to 4 carbon atoms.

On the other hand, R₂ in the formula (A) is a residual group which contributes to an improvement in etch resistance. Illustrative are tricyclo[5.2.1.0^{2.6}]decyl, norbornyl, methylnorbornyl, isobornyl, tetracyclo[4.4.0.1^{2.5}.1^{7.10}]dodecyl, methyltetracyclo[4.4.0.1^{2.5}.1^{7.10}]dodecyl, 2,7-dimethyltetracyclo[4.4.0.1^{2.5}.1^{7.10}]dodecyl, 2,10-dimethyltetracyclo[4.4.0.1^{2.5}. 1^{7.10}]dodecyl, 11,12-dimethyltetracyclo[4.4.0.1^{2.5}.1^{7.10}]dodecyl, octacyclo[8.8.1^{2.9}.1^{4.7}.1^{11.18}.1^{13.16}.0.0^{3.8}.0^{12.17}]docosyl and adamantanyl, and derivatives thereof.

The R₆-containing structural unit in the formula (A) is a unit which contributes to an improvement in substrate adhesion. R₆ is a hydrogen atom or a γ-butyrolactone residual group (γ-butyrolactonyl group) represented by the following formula:

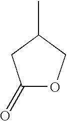

As these protecting groups R₄ themselves impart excellent etch resistance, the resist resin of the present invention represented by the formula (A) can retain sufficient etch resistance even if the percentage m of the units each of which contains the protecting group is increased and the percentage l of the units each of which contains the etch resistant group is decreased. Accordingly, the balance in properties among etch resistance, resist resolution and substrate adhesion has been markedly improved compared with the conventional art.

In the formula (A), l can be set preferably at 35 to 75, more preferably at 40 to 50. m can be set preferably at 10 to 50, more preferably at 10 to 40. Further, n can be set preferably at 15 to 50, more preferably at 20 to 45.

The carbon density of the resist resin of the formula (A) may preferably be 3.1 or lower. The carbon density a is defined by:

α=N/(N_{C}−N_{O})

where

N means a total number of atoms in the resist resin,

N_{C} means a number of carbon atoms in the resist resin and

N_{O} means a number of oxygen atoms in the resist resin.

The value of the carbon density of the resist resin can be calculated by determining the carbon densities of the respective types of structural units in accordance with the above formula, multiplying the carbon densities with the corresponding percentages, and then obtaining the sum of the products.

The resist resin represented by the formula (A) can be obtained by subjecting the corresponding monomers to solution polymerization in the presence of a radical polymerization initiator. For example, it can be produced by heating the corresponding monomers together with a radical initiator such as azobisisobutyronitrile with stirring in a solvent such as tetrahydrofuran under an inert gas atmosphere such as argon or nitrogen. The average polymerization degree of the resist resin may be 10 to 500, preferably 10 to 200, and its weight average molecular weight may be 1,000 to 500,000, with 1,000 to 100,000 being more preferred.

The chemically amplified resist composition according to the present invention comprises the above-described resist resin and a photoacid generator.

Concerning the contents of the resist resin and the photoacid generator, the latter may be set at 0.2 to 25 wt. % relative to 75 to 99.8 wt. % of the former, and preferably, the latter may be set at 1 to 15 wt. % relative to 85 to 99 wt. % of the former. Setting at such a proportion makes it possible to obtain very good resolution, to provide a coating film with still better thickness uniformity, and further to effectively prevent occurrence of a residue (scum) after development.

No particular limitation is imposed on the photoacid generator for use in the present invention, insofar as its mixture with the resist resin according to the present invention and other optional components is sufficiently soluble in an organic solvent and the resulting solution can be formed into a uniform coating film by a film forming method such as spin coating. Desirably, it can be such a photoacid generator that gives off an acid when exposed to light of 200 nm or shorter in wavelength. Such photoacid generators can be used either singly or in combination, and further in combination with an appropriate sensitizer.

Illustrative of usable photoacid generators are triphenylsulfonium salt derivatives such as triphenylsulfonium trifluoromethanesulfonate, other onium salts represented by such triphenylsulfonium salt derivatives (for example, compounds such as sulfonium salts, iodonium salts, phosphonium salts, diazonium salts and ammonium salts), 2,6-dinitrobenzyl esters, 1,2,3-tri(methanesulfonyloxy)benzene, sulfosuccinimide, and compounds represented by the following formula (C) or formula (D):

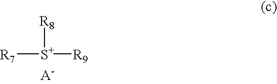

wherein R₇ and R₈ each independently represent a linear, branched or cyclic alkyl group, R₉ represents a linear, branched or cyclic alkyl group, a 2-oxocycloalkyl group or a 2-oxo(linear or branched)alkyl group, and A⁻ represents a counter ion such as BF₄⁻, AsF₆⁻, SbF₆⁻, PF₆⁻, CF₃COO⁻, CIO₄⁻, CF₃SO₃⁻, an alkylsulfonato or an arylsulfonato.

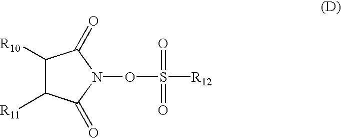

wherein R₁₀ and R₁₁ each independently represent a hydrogen atom or a linear, branched or cyclic alkyl group, R₁₂ represents a linear, branched or cyclic alkyl group or a haloalkyl group represented by a perfluoroalkyl such as trifluoromethyl.

When exposure light of 200 nm or shorter in wavelength is used and an importance is placed on enhancing light transmission properties, use of a photoacid generator represented by the formula (C) or a photoacid generator represented by the formula (D) is more desired, because both of these photoacid generators exhibit extremely low absorption for light in a far-ultraviolet region of from 185.5 to 200 nm and are excellent in transparency to such exposure light. Specific examples include cyclohexylmethyl(2-oxocyclohexyl)sulfonium trifluoromethanesulfonate, dicyclohexyl(2-oxocyclohexyl)sulfonium trifluoromethanesulfonate, dicyclohexylsulfonyl cyclohexanone, dimethyl(2-oxocyclohexyl)sulfonium trifluoromethanesulfonate, triphenylsulfonium trifluoromethanesulfonate, diphenyliodonium trifluoromethanesulfonate, and N-hydroxysuccinimide trifluoromethanesulfonate.

To coat the above-described resist composition onto a substrate, it is possible to adopt such a process that the composition is either dissolved or dispersed in a solvent and the resulting solution is coated by spin coating. Any solvent can be used preferably, insofar as it is such an organic solvent that components consisting of a high-molecular compound, an alkylsulfonium salt and other optional components can be sufficiently dissolved and the resulting solution can be formed into a uniform coating film by a coating method such spin coating. Such solvents can be used either singly or in combination. Specific examples include n-propyl alcohol, isopropyl alcohol, n-butyl alcohol, tert-butyl alcohol, methylcellosolve acetate, ethylcellosolve acetate, propylene glycol monoethyl ether acetate, methyl lactate, ethyl lactate, 2-ethoxybutyl acetate, 2-ethoxyethyl acetate, methyl pyruvate, ethyl pyruvate, methyl 3-methoxypropionate, ethyl 3-methoxypropionate, N-methyl-2-pyrrolidinone, cyclohexanone, cyclopentanone, cyclohexanol, methyl ethyl ketone, 1,4-dioxane, ethylene glycol monomethyl ether, ethylene glycol monomethyl ether acetate, ethylene glycol monoethyl ether, ethylene glycol monoisopropyl ether, diethylene glycol monomethyl ether, and diethylene glycol dimethyl ether.

To the chemically amplified resist composition according to the present invention, other components such as surfactants, colorants, stabilizers, coating property improvers and dyes can be added as desired.

As a developer upon conducting formation of a submicrometer pattern with the chemically amplified resist composition of the present invention, an appropriate organic solvent or a mixed solvent thereof or an alkaline solution of an adequate concentration in a solvent or water or a mixture of such solutions can be chosen depending on the solubility of the high-molecular compound employed in the present invention. Examples of usable organic solvents include ketones such as acetone, methyl ketone, methyl isobutyl ketone, cyclopentanone, and cyclohexanone; alcohols such as methyl alcohol, ethyl alcohol, n-propyl alcohol, isopropyl alcohol, n-butyl alcohol, isobutyl alcohol, tert-butyl alcohol, cyclopentanol, and cyclohexanol; and other organic solvents such as tetrahydrofuran, dioxane, ethyl acetate, butyl acetate, isoamyl acetate, toluene, xylene, and phenol. On the other hand, examples of usable alkaline solutions include aqueous solutions and organic solvent solutions containing inorganic alkalis such as sodium hydroxide, potassium hydroxide, sodium silicate and ammonia, organic amines such as ethylamine, propylamine, diethylamine, dipropylamine, trimethylamine and triethylamine, and organic ammonium salts such as tetramethylammonium hydroxide, tetraethylammonium hydroxide, trimethylhydroxymethylammonium hydroxide, triethylhydroxymethylammonium hydroxide and trimethylhydroxyethylammonium hydroxide; and mixtures of such solutions.

The chemically amplified resist composition of the present invention can be rendered capable of also exhibiting pattern-forming ability tog or i beams from mercury-vapor lamps, the KrF excimer laser, electron beams and x rays as other high-energy radiations by introducing appropriate photoacid generators or colorants suitable for the absorption of such light.

The pattern forming process according to the present invention is characterized in that it comprises coating the above-described chemically amplified resist composition according to the present invention onto a substrate, heating the resulting coating film, exposing the heated coating film to high-energy radiation, subjecting the exposed coating film to heat treatment, and then developing the heat-treated coating film to form a pattern.

As the high-energy radiation, use of light of 200 nm or shorter in wavelength is preferred. It is particularly preferred to use a shortwave laser such as the ArF excimer laser or the F₂ laser.

### EXAMPLES

Firstly, a description will be made about chemically amplified resist compositions used in the Examples. Each of those compositions had the following formulation:

| | |
|---|---|
| Resist resin: | 95 wt. % |
| Photoacid generator: | 5 wt. % |

Solutions of those resist compositions (16 wt. %) in a solvent (84 wt. %) were separately coated on substrates.

The used resist resins and photoacid generator will be specified hereinafter.

(i) Resist Resins

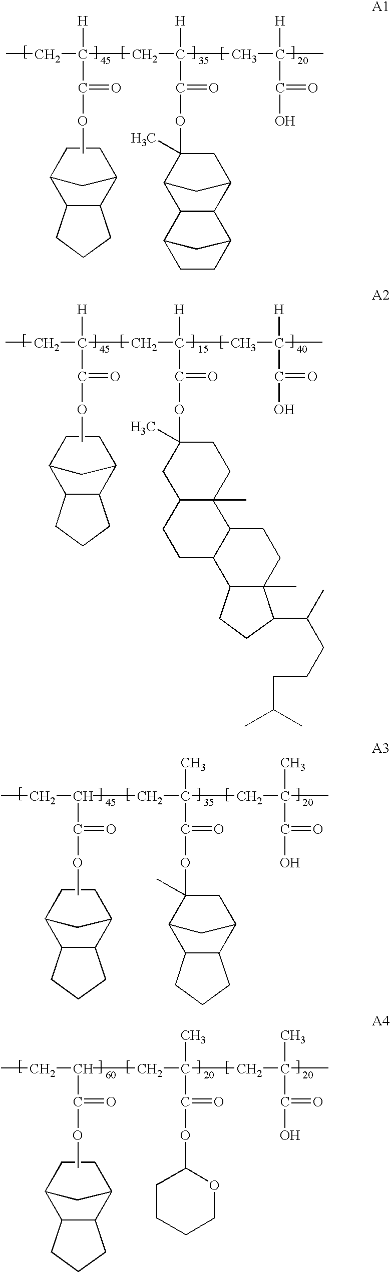

The above-described resist resins can each be obtained by subjecting the corresponding monomers to solution polymerization in the presence of a radical polymerization initiator. For example, A1 and A2 were produced as will be described below.

Production Process of A1

Added dropwise into a solution of tetracyclododecan-4-one in diethyl ether, said solution having been chilled to −50° C., was a solution of methyllithium in diethyl ether, said solution having been chilled to −50° C. The resulting mixture was heated to 0° C., followed by the dropwise addition of methacrylic acid chloride. Subsequent to completion of the dropwise addition, the temperature of the thus-obtained mixture was allowed to rise room temperature, at which it was stirred for a predetermined time. An organic layer, which had been obtained by filtration, was washed with an aqueous solution of sodium hydrogen carbonate and then with water. The mixture was thereafter concentrated to afford 4-methyl-4-tricyclododecyl methacrylate. Subsequently, tricyclodecanyl acrylate, the 4-methyl-4-tricyclododecyl methacrylate and methacrylic acid were charged at a molar ratio of 45:35:20, azobisisobutyronitrile was added as apolymerization initiator, and the resulting mixture was held under heat. The thus-obtained reaction product was allowed to precipitate and was purified to afford the resist resin A1. The weight average molecular weight of the resist resin was 10,000.

Production Process of A2

Added dropwise into a solution of 5α-cholestan-3-one (commercial product) in diethyl ether, said solution having been chilled to −50° C., was a solution of methyllithium in diethyl ether, said solution having been chilled to −50° C. The resulting mixture was heated to 0° C., followed by the dropwise addition of methacrylic acid chloride. Subsequent to completion of the dropwise addition, the temperature of the thus-obtained mixture was allowed to rise to room temperature, at which it was stirred for a predetermined time. An organic layer, which had been obtained by filtration, was washed with an aqueous solution of sodium hydrogencarbonate and then with water. The mixture was thereafter concentrated to afford 3-methyl-3-cholestanyl methacrylate. Tricyclodecanyl acrylate, the 3-methyl-3-cholestanyl methacrylate and methacrylic acid were charged at a molar ratio of 45:15:40, azobisisobutyronitrile was added as a polymerization initiator, and the resulting mixture was held under heat. The thus-obtained reaction product was allowed to precipitate and was purified to afford the resist resin A2. The weight average molecular weight of the resist resin was 10,000.

Each of the remaining resist resins A3, A4 ,A5 was also obtained likewise by subjecting the corresponding monomers to solution polymerization in the presence of the radical polymerization initiator. Their weight average molecular weights were all about 10,000.

(ii) Photoacid Generator

Triphenylsulfonium trifluoromethanesulfonate was used.

The above-described five types of resist resins were separately dissolved together with triphenylsulfonium trifluoromethanesulfonate in ethyl lactate to obtain five types of resist solutions.

### Example 1

The individual resist resins were evaluated for etch resistance in this Example.

The resist solutions—which contained the resist resins A1 to A5, respectively, and the photoacid generator—were separately spin-coated on silicon wafers, and then baked on hot plates to form thin resist films of 0.4 μm in thickness.

Using a reactive ion etching (RIE) system, the etch rates of the resultant films by Cl₂ gas were measured.

As a control, the etch rate of an i-line resist resin (“PFI-38”; product of Sumitomo Chemical Co., Ltd.) was measured.

The etch resistance of each resist was evaluated in terms of the ratio of its etch rate to the etch rate of the i-line resist resin when the latter was assumed to be 1. Described specifically, the value obtained by dividing the etch rate of each resist resin with the dry etch rate of the i-line resist resin was employed as a ratio of etch rate. The lower the value of this ratio of etch rate, the resist resin was evaluated to have higher etch resistance.

Further, the carbon density α of each resist resin was calculated as will be described hereinafter. Firstly, with respect to the respective types of units making up the resist resin, their carbon densities α were determined, respectively. The carbon densities of the respective types of units were then multiplied by their corresponding contents, and their products were summed up. In this manner, the overall carbon density of the resist resin was determined.

The results of the evaluation are presented in Table 1. From the viewpoint of practical use, the ratio of etch rate (relative to the i-line resist) is desired to be 1.5 or smaller. The resist resins according to the present invention were confirmed to have excellent etch resistance sufficient to meet the requirement for practical use.

In addition, the transmittances of thin films (thickness: 0.4 μm) of the resist resins designated by A1 and A2 to the ArF excimer laser beam (193 nm) were measured. Values as high as 65% or greater were obtained. Those resist resins were also found to have good adhesion to silicon substrates.

TABLE 1

| Sample No. | Resist resin | Carbon density | Ratio of etch rate |
|---|---|---|---|
| 1 | A1 | 3.07 | 1.34 |
| 2 | A2 | 2.73 | 0.66 |
| 3 | A3 | 3.19 | 1.57 |
| 4 | A4 | 3.43 | 2.05 |
| 5 | A5 | 3.39 | 1.98 |

### Example 2

After a resist composition with Al contained therein was spin-coated on an antireflection film (“AR19”; thickness: 82 nm; product of Shipley Company LLC), the coating film was prebaked at 80° C. for 1 minute on a hot plate. Using an ArF excimer laser exposure system (manufactured by Nikon Corporation; NA=0.60), the prebaked coating film was selectively exposed to an ArF laser beam of 193 nm in wavelength through a reticle with L&S patterns of various widths drawn thereon. The exposure energy was set at 20.0 mJ/cm².

The resist film was then subjected to post exposure bake (PEB) at 130° C. for 90 seconds on a hot plate. Subsequently, the exposed resist film was dipped in an alkaline developer (2.38 wt. % aqueous solution of tetramethylammonium hydroxide), followed by rinsing with pure water. As a result, the resist film was dissolved off at exposed parts to give patterns.

When the resist pattern so obtained was observed under an electron microscope, formation of good patterns was confirmed up to 0.12 μm L&S. Further, problems such as undeveloped areas and pattern peeling were not observed.

On the other hand, a resist composition with A3 contained therein was also evaluated likewise. It was possible to form, with good resolution, patterns up to only 0.17 μm L&S.

What is claimed is:

1. A resist resin having a molecular structure in which protecting groups bond to a base resin such that elimination of said protecting groups from said resist resin increases its alkali-solubility, wherein:
said protecting groups are residual groups represented by the following formula (I): 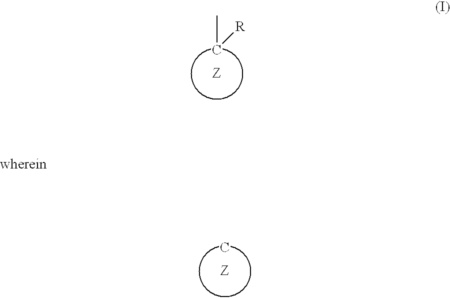
represents a substituted or unsubstituted, fused ring having 12 to 25 carbon atoms, and R represents an alkyl group having 1 to 4 carbon atoms.

2. A resist resin according to claim 1, wherein 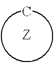
in said formula (I) is a tricyclo[5.2.1.0^{2.6}]decyl group, hexacyclo[6.6.1.1^{3.6}.1^{10.13}.0^{2.7}.0^{9.14}]heptadecyl group, octacyclo[8.8.1^{2.9}.1^{4.7}.1^{11.18}.1^{13.16}.0.0^{3.8}.0^{12.17}]docosyl group or cholestanyl group, or a derivative thereof.

3. A resist resin according to claim 1, wherein said protecting groups are residual groups represented by the following formula (II): 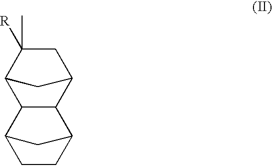
wherein R represents an alkyl group having 1 to 4 carbon atoms.

4. A resist resin according to claim 1, wherein said protecting groups are residual groups represented by the following formula (III): 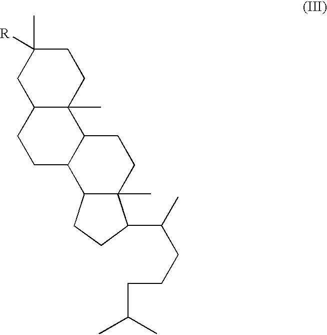
wherein R represents an alkyl group having 1 to 4 carbon atoms.

5. A resist resin according to any one of claims 1-4, wherein α, which is defined by the following formula:
α=N/(N_{C}−N_{O})
where
N means a total number of atoms in said resist resin,
N_{C} means a number of carbon atoms in said resist resin and
N_{O} means a number of oxygen atoms in said resist resin, is not greater than 3.1.

6. A resist resin according to any one of claims 1-4, a molecular structure of which contains no aromatic ring therein.

7. A resist resin according to claim 5, a molecular structure of which contains no aromatic ring therein.

8. A resist resin, comprising units represented by the following formula (A): 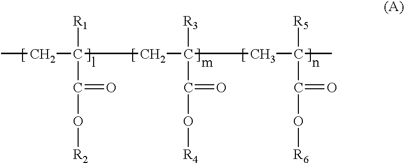
wherein R₁, R₃ and R₅ each independently represent a hydrogen atom or a methyl group, R₂ represents an alicyclic hydrocarbon group having 7 to 25 carbon atoms, a protecting group R₄ is a residual group represented by the following formula (I): 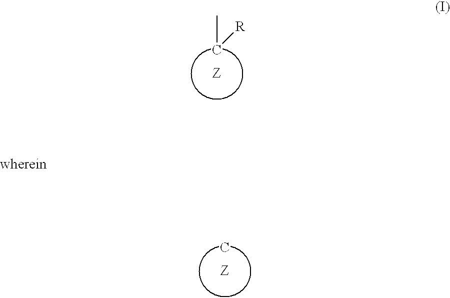
represents a substituted or unsubstituted, fused ring having 12 to 25 carbon atoms, R represents an alkyl group having 1 to 4 carbon atoms, R₆ represents a hydrogen atom or a γ-butyrolactonyl group, l, m and n each represent the content by percentage of the units, l+m+n=100, 0<l<100, 0<m<100, and 0<n<100.

9. A resist resin according to claim 8, wherein 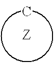
in said protecting group R₄ is atricyclo[5.2.1.0^{2.6}]decyl group, hexacyclo[6.6.1.1^{3.6}.1^{10.13}.0^{2.7}.0^{9.14}]heptadecyl group, octacyclo[8.8.1^{2.9}.1^{4.7}.1^{11.18}.1^{13.16} .0.0^{3.8}.0^{12.17} ]docosyl group or cholestanyl group, or a derivative thereof.

10. A resist resin according to claim 8, wherein said protecting group R₄ is a residual group represented by the following formula (II) 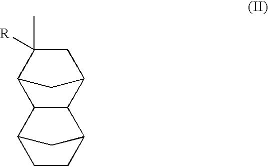
wherein R represents an alkyl group having 1 to 4 carbon atoms.

11. A resist resin according to claim 8, wherein said protecting group R₄ is a residual group represented by the following formula (III) 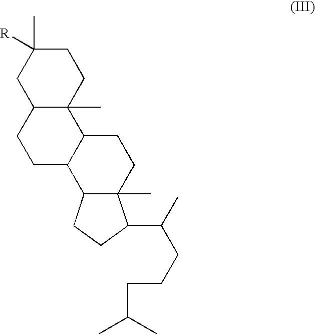
wherein R represents an alkyl group having 1 to 4 carbon atoms.

12. A resist resin according to any one of claims 8-11, wherein α, which is defined by the following formula:
α=N/(N_{C}−N_{O})
where
N means a total number of atoms in said resist resin,
N_{C} means a number of carbon atoms in said resist resin and
N_{O} means a number of oxygen atoms in said resist resin, is not greater than 3.1.

13. A resist resin according to any one of claims 8-11, wherein R₂ in said formula (A) is a residual group selected from the group consisting of a tricyclo[5.2.1.0^{2.6}]decyl group, hexacyclo[6.6.1.1^{3.6}.1^{10.13} .0^{2.7}.0^{9.14} ]heptadecyl group, octacyclo[8.8.1^{2.9}.1^{4.7}.1^{11.18}.1^{13.16}.0.0^{3.8}.0^{12.17}]docosyl group, adamantanyl group and derivatives thereof.

14. A resist resin according to claims 12, wherein R₂ in said formula (A) is a residual group selected from the group consisting of a tricyclo[5.2.1.0^{2.6}]decyl group, hexacyclo[6.6.1.1^{3.6}.1^{10.13}.0^{2.7}.0^{9.14}]heptadecyl group, octacyclo[8.8.1^{2.9}.1^{4.7}.1^{11.18}.1^{13.16}.0.0^{3.8}.0^{12.17}]docosyl group, adamantanyl group and derivatives thereof.

15. A chemically amplified resist composition comprising 75 to 99.8 wt. % of a resist resin according to claim 1 or 8 and 0.2 to 25 wt. % of a photoacid generator.

16. A process for the formation of a pattern, comprising the steps of:
coating a chemically amplified resist composition according to claim 15 onto a substrate;
heating a resulting coating film; exposing said heated coating film to high-energy radiation;
subjecting said exposed coating film to heat treatment; and
developing said heat-treated coating film to form said pattern.

17. A process for the formation of a pattern according to claim 16, wherein light having a wavelength not longer than 200 nm is used as said high-energy radiation.

18. A process for the formation of a pattern according to claim 17, wherein ArF excimer laser is used as said high-energy radiation.
